(19) United States
(12) Patent Application Publication
(10) Pub. No.: US 2024/0136999 A1
(43) Pub. Date: Apr. 25, 2024

(54) ACOUSTIC WAVE DEVICE

(71) Applicant: Murata Manufacturing Co., Ltd., Nagaokakyo-shi (JP)

(72) Inventor: Tetsuya KIMURA, Nagaokakyo-shi (JP)

(21) Appl. No.: 18/401,759

(22) Filed: Jan. 2, 2024

Related U.S. Application Data
(63) Continuation of application No. PCT/JP2022/026738, filed on Jul. 5, 2022.
(60) Provisional application No. 63/219,399, filed on Jul. 8, 2021.

(51) Int. Cl. H03H 9/02; H03H 9/05; H03H 9/145; H03H 9/25

(52) U.S. Cl. CPC H03H 9/02574; H03H 9/0538; H03H 9/14541; H03H 9/14547; H03H 9/25

(57) ABSTRACT

An acoustic wave device includes a support substrate with a thickness in a first direction, an intermediate layer on the support substrate, a piezoelectric layer on the intermediate layer, and an interdigital transducer electrode including a first electrode finger on a surface of the piezoelectric layer and extending in a second direction intersecting the first direction, a first busbar electrode connected to the first electrode finger, a second electrode finger opposed to the first electrode finger in a third direction orthogonal or substantially orthogonal to the second direction and extending in the second direction, and a second busbar electrode connected to the second electrode finger. The intermediate layer includes a space in a region in which at least a portion of the intermediate layer overlaps the interdigital transducer electrode in a plan view in the first direction, and an inner wall of the space includes at least one notch.

### CROSS REFERENCE TO RELATED APPLICATIONS

This application claims the benefit of priority to Provisional Application No. 63/219,399 filed on Jul. 8, 2021 and is a Continuation Application of PCT Application No. PCT/JP2022/026738 filed on Jul. 5, 2022. The entire contents of each application are hereby incorporated herein by reference.

### BACKGROUND OF THE INVENTION

### 1. Field of the Invention

The present disclosure relates to acoustic wave devices.

### 2. Description of the Related Art

Japanese Unexamined Patent Application Publication No. 2012-257019 describes an acoustic wave device.

The acoustic wave device described in Japanese Unexamined Patent Application Publication No. 2012-257019 generates heat during operation. At this time, because the coefficient of linear expansion of a busbar electrode of a functional electrode is greater than the coefficient of linear expansion of a piezoelectric layer, the characteristics may degrade due to warpage of the piezoelectric layer.

### SUMMARY OF THE INVENTION

Example embodiments of the present invention reduce or prevent warpage of a piezoelectric layer.

An acoustic wave device according to an example embodiment of the present invention includes a support substrate with a thickness in a first direction, an intermediate layer on the support substrate, a piezoelectric layer on the intermediate layer, and an interdigital transducer electrode including a first electrode finger on a principal surface of the piezoelectric layer and extending in a second direction that intersects with the first direction, a first busbar electrode connected to the first electrode finger, a second electrode finger opposed to the first electrode finger in a third direction orthogonal or substantially orthogonal to the second direction and extending in the second direction, and a second busbar electrode connected to the second electrode finger. The intermediate layer includes a space in a region in which at least a portion of the intermediate layer overlaps the interdigital transducer electrode in a plan view in the first direction, and an inner wall of the space includes at least one notch.

An acoustic wave device according to an example embodiment of the present invention includes a support substrate with a thickness in a first direction, a piezoelectric layer on the support substrate, and an interdigital transducer electrode including a first electrode finger on a principal surface of the piezoelectric layer and extending in a second direction that intersects with the first direction, a first busbar electrode connected to the first electrode finger, a second electrode finger opposed to the first electrode finger in a third direction orthogonal or substantially orthogonal to the second direction and extending in the second direction, and a second busbar electrode connected to the second electrode finger. The support substrate includes a space in a region in which at least a portion of the support substrate overlaps the interdigital transducer electrode in a plan view in the first direction, and an inner wall of the space includes at least one notch.

According to example embodiments of the present invention, it is possible to reduce or prevent warpage of a piezoelectric layer.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1A is a perspective view of an acoustic wave device according to an example embodiment of the present invention.

FIG. 1B is a plan view of an electrode structure according to an example embodiment of the present invention.

FIG. 2 is a cross-sectional view taken along the line II-II in FIG. 1A.

FIG. 3A is a schematic cross-sectional view for illustrating Lamb waves that propagate in a piezoelectric layer according to a comparative example.

FIG. 3B is a schematic cross-sectional view for illustrating bulk waves in a first thickness-shear mode, which propagate in a piezoelectric layer according to an example embodiment of the present invention.

FIG. 4 is a schematic cross-sectional view for illustrating bulk waves in a first thickness-shear mode in an amplitude direction, which propagate in a piezoelectric layer according to an example embodiment of the present invention.

FIG. 5 is a graph that illustrates an example of the resonant characteristics of an acoustic wave device according to an example embodiment of the present invention.

FIG. 6 is a graph that illustrates the relationship between d/2p and a fractional band width as a resonator where a center-to-center distance between adjacent electrodes or an average distance of center-to-center distances between the adjacent electrodes is p and an average thickness of the piezoelectric layer is d in an acoustic wave device according to an example embodiment of the present invention.

FIG. 7 is a plan view of an example in which a pair of electrodes is provided in an acoustic wave device according to an example embodiment of the present invention.

FIG. 8 is a reference graph of an example of the resonant characteristics of an acoustic wave device according to an example embodiment of the present invention.

FIG. 9 is a graph that illustrates the relationship between a fractional band width in the case where a large number of acoustic wave resonators are provided and a phase rotation amount of impedance of spurious normalized by 180 degrees as the magnitude of spurious in an acoustic wave device according to an example embodiment of the present invention.

FIG. 10 is a graph that illustrates the relationship among d/2p, metallization ratio MR, and fractional band width.

FIG. 11 is a diagram that illustrates a map of a fractional band width for the Euler angles (0°, θ, ψ) of LiNbO₃ when d/p is brought close to zero without limit.

FIG. 12 is a partially cutaway perspective view for illustrating an acoustic wave device according to an example embodiment of the present invention.

FIG. 13 is a perspective view of an example of an acoustic wave device according to an example embodiment of the present invention.

FIG. 14 is a cross-sectional view taken along the line XV-XV in FIG. 13.

FIG. 15 is a perspective view of a support of the acoustic wave device shown in FIG. 13.

FIG. 16A is a view that shows a distribution of displacement in a Z direction of a piezoelectric layer of an acoustic wave device according to Comparative Example 1.

FIG. 16B is a view that shows a distribution of displacement in a Z direction of a piezoelectric layer of an acoustic wave device according to Example 1.

FIG. 16C is a view that shows a distribution of displacement in a Z direction of a piezoelectric layer of an acoustic wave device according to Example 2.

FIG. 16D is a view that shows a distribution of displacement in a Z direction of a piezoelectric layer of an acoustic wave device according to Example 3.

FIG. 16E is a view that shows a distribution of displacement in a Z direction of a piezoelectric layer of an acoustic wave device according to Example 4.

FIG. 16F is a view that shows a distribution of displacement in a Z direction of a piezoelectric layer of an acoustic wave device according to Example 5.

FIG. 17 is a graph that shows a displacement in the Z direction along the A-A′ line in FIG. 13 of each of the piezoelectric layers of the acoustic wave devices according to Comparative Example 1 and Example 1 to Example 5.

FIG. 18 is a graph that shows an average value of displacement in the Z direction along the A-A′ line in FIG. 13 of each of the piezoelectric layers of the acoustic wave devices according to Comparative Example 1 and Example 1 to Example 5.

FIG. 19A is a view that shows a distribution of displacement in a Z direction of a piezoelectric layer of an acoustic wave device according to Comparative Example 2.

FIG. 19B is a view that shows a distribution of displacement in a Z direction of a piezoelectric layer of an acoustic wave device according to Example 6.

FIG. 19C is a view that shows a distribution of displacement in a Z direction of a piezoelectric layer of an acoustic wave device according to Example 7.

FIG. 19D is a view that shows a distribution of displacement in a Z direction of a piezoelectric layer of an acoustic wave device according to Example 8.

FIG. 19E is a view that shows a distribution of displacement in a Z direction of a piezoelectric layer of an acoustic wave device according to Example 9.

FIG. 19F is a view that shows a distribution of displacement in a Z direction of a piezoelectric layer of an acoustic wave device according to Example 10.

FIG. 20 is a graph that shows a displacement in the Z direction along the A-A′ line in FIG. 13 of each of the piezoelectric layers of the acoustic wave devices according to Comparative Example 2 and Example 6 to Example 10.

FIG. 21 is a graph that shows an average value of displacement in the Z direction along the A-A′ line in FIG. 13 of each of the piezoelectric layers of the acoustic wave devices according to Comparative Example 2 and Example 6 to Example 10.

FIG. 22A is a view that shows a distribution of displacement in a Z direction of a piezoelectric layer of an acoustic wave device according to Comparative Example 3.

FIG. 22B is a view that shows a distribution of displacement in a Z direction of a piezoelectric layer of an acoustic wave device according to Example 11.

FIG. 22C is a view that shows a distribution of displacement in a Z direction of a piezoelectric layer of an acoustic wave device according to Example 12.

FIG. 22D is a view that shows a distribution of displacement in a Z direction of a piezoelectric layer of an acoustic wave device according to Example 13.

FIG. 22E is a view that shows a distribution of displacement in a Z direction of a piezoelectric layer of an acoustic wave device according to Example 14.

FIG. 22F is a view that shows a distribution of displacement in a Z direction of a piezoelectric layer of an acoustic wave device according to Example 15.

FIG. 23 is a graph that shows a displacement in the Z direction along the A-A′ line in FIG. 13 of each of the piezoelectric layers of the acoustic wave devices according to Comparative Example 3 and Example 11 to Example 15.

FIG. 24 is a graph that shows an average value of displacement in the Z direction along the A-A′ line in FIG. 13 of each of the piezoelectric layers of the acoustic wave devices according to Comparative Example 3 and Example 11 to Example 15.

### DETAILED DESCRIPTION OF THE EXAMPLE EMBODIMENTS

Hereinafter, example embodiments of the present invention will be described in detail with reference to the accompanying drawings. The present invention is not limited to the example embodiments. Each of the example embodiments described in the present disclosure is illustrative and partial replacements or combinations of components are possible among different example embodiments. In the modifications, second and following example embodiments, the description of the same or similar matters to those of the first example embodiment is omitted, and only the differences will be described. Particularly, similar operations and advantageous effects with the same or similar components will not be repeated one by one for each example embodiment.

### Example Embodiment

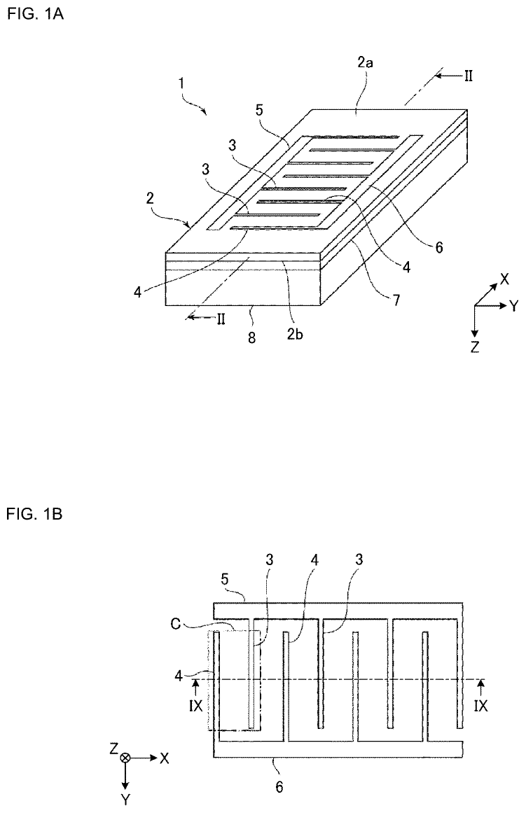

FIG. 1A is a perspective view of an acoustic wave device according to an example embodiment. FIG. 1B is a plan view of an electrode structure according to the present example embodiment.

The acoustic wave device 1 according to the present example embodiment includes a piezoelectric layer 2 made of, for example, LiNbO₃. The piezoelectric layer 2 may be made of, for example, LiTaO₃. The cut angle of LiNbO₃ or LiTaO₃ is Z-cut in the present example embodiment. The cut angle of LiNbO₃ or LiTaO₃ may be rotated Y-cut or X-cut. Preferably, a propagation direction of, for example, about ±30° with respect to Y propagation or X propagation is preferable.

The thickness of the piezoelectric layer 2 is not limited and is preferably, for example, greater than or equal to about 50 nm and less than or equal to about 1000 nm to effectively excite a first thickness-shear mode.

The piezoelectric layer 2 includes a first principal surface 2a and a second principal surface 2b opposed to each other in a Z direction. Electrode fingers 3 and electrode fingers 4 are provided on the first principal surface 2a.

Here, the electrode fingers 3 are examples of the first electrode finger, and the electrode fingers 4 are examples of the second electrode finger. In FIGS. 1A and 1B, the plurality of electrode fingers 3 are a plurality of first electrode fingers connected to a first busbar electrode 5. The plurality of electrode fingers 4 are a plurality of second electrode fingers connected to a second busbar electrode 6. The plurality of electrode fingers 3 and the plurality of electrode fingers 4 are interdigitated with each other. Thus, an interdigital transducer (IDT) electrode including the electrode fingers 3, the electrode fingers 4, the first busbar electrode 5, and the second busbar electrode 6 is provided.

The electrode fingers 3 and the electrode fingers 4 each have a rectangular or substantially rectangular shape and have a length direction. In a direction orthogonal or substantially orthogonal to the length direction, each of the electrode fingers 3 and an adjacent one of the electrode fingers 4 are opposed to each other. The length direction of the electrode fingers 3 and electrode fingers 4 and the direction orthogonal or substantially orthogonal to the length direction of the electrode fingers 3 and electrode fingers 4 both are directions that intersect with a thickness direction of the piezoelectric layer 2. For this reason, each of the electrode fingers 3 and one of the electrode fingers 4, adjacent to the electrode finger 3, may be regarded as being opposed to each other in the direction that intersects with the thickness direction of the piezoelectric layer 2. In the following description, the description can be made on the assumption that the thickness direction of the piezoelectric layer 2 is a Z direction (or first direction), the length direction of the electrode fingers 3 and electrode fingers 4 is a Y direction (or second direction), and the direction orthogonal or substantially orthogonal to the electrode fingers 3 and the electrode fingers 4 is an X direction (or third direction).

Alternatively, the length direction of the electrode fingers 3 and electrode fingers 4 may be interchanged with the direction orthogonal or substantially orthogonal to the length direction of the electrode fingers 3 and electrode fingers 4, shown in FIGS. 1A and 1B. In other words, in FIGS. 1A and 1B, the electrode fingers 3 and the electrode fingers 4 may extend in a direction in which the first busbar electrode 5 and the second busbar electrode 6 extend. In this case, the first busbar electrode 5 and the second busbar electrode 6 extend in the direction in which the electrode fingers 3 and the electrode fingers 4 extend in FIGS. 1A and 1B. A plurality of pairs of adjacent electrode fingers 3, 4 respectively connected to one potential and the other potential are provided in the direction orthogonal to the length direction of the electrode fingers 3 and electrode fingers 4.

Here, a state where the electrode finger 3 and the electrode finger 4 are adjacent to each other does not mean a case where the electrode finger 3 and the electrode finger 4 are in direct contact with each other and means a case where the electrode finger 3 and the electrode finger 4 are disposed with a gap therebetween. When the electrode finger 3 and the electrode finger 4 are adjacent to each other, no electrode connected to a hot electrode or a ground electrode, including the other electrode fingers 3 and electrode fingers 4, is disposed between the electrode finger 3 and the electrode finger 4. The number of the pairs is not necessarily an integer number of pairs and may be 1.5 pairs, 2.5 pairs, or the like.

A center-to-center distance between the electrode finger 3 and the electrode finger 4, that is, a pitch, preferably falls within the range of, for example, greater than or equal to about 1 μm and less than or equal to about 10 μm. A center-to-center distance between the electrode finger 3 and the electrode finger 4 is a distance between the center of the width dimension of the electrode finger 3 in the direction orthogonal or substantially orthogonal to the length direction of the electrode finger 3 and the center of the width dimension of the electrode finger 4 in the direction orthogonal or substantially orthogonal to the length direction of the electrode finger 4.

In addition, when at least one of the number of electrode fingers 3 and the number of electrode fingers 4 is more than one (when, where the electrode finger 3 and the electrode finger 4 are assumed as a paired electrode set, 1.5 or more pairs of the electrode sets), the center-to-center distance between the electrode finger 3 and the electrode finger 4 means an average value of the center-to-center distance between any adjacent electrode finger 3 and electrode finger 4 of the 1.5 or more pairs of the electrode finger 3 and electrode finger 4.

The width of each of the electrode finger 3 and the electrode finger 4, that is, the dimension of each of the electrode finger 3 and the electrode finger 4 in the opposed direction, preferably falls within the range of, for example, greater than or equal to about 150 nm and less than or equal to about 1000 nm. A center-to-center distance between the electrode finger 3 and the electrode finger 4 is a distance between the center of the dimension (width dimension) of the electrode finger 3 in the direction orthogonal or substantially orthogonal to the length direction of the electrode finger 3 and the center of the dimension (width dimension) of the electrode finger 4 in the direction orthogonal to the length direction of the electrode finger 4.

In the present example embodiment, since the Z-cut piezoelectric layer is used, the direction orthogonal or substantially orthogonal to the length direction of the electrode fingers 3 and electrode fingers 4 is a direction orthogonal or substantially orthogonal to a polarization direction of the piezoelectric layer 2. When a piezoelectric body with another cut angle is used as the piezoelectric layer 2, this does not apply. Here, the term “orthogonal” is not limited only to a strictly orthogonal case and may be substantially orthogonal (an angle formed between the direction orthogonal to the length direction of the electrode fingers 3 and electrode fingers 4 and the polarization direction is, for example, about 90°±10°).

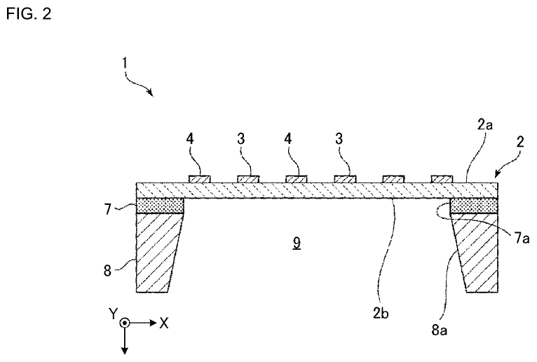

A support substrate 8 is laminated to the second principal surface 2b of the piezoelectric layer 2 with an intermediate layer 7 interposed therebetween. As shown in FIG. 2, the intermediate layer 7 has a frame shape and includes a cavity 7a, and the support substrate 8 has a frame shape and includes a cavity 8a. With this configuration, a space (air gap) 9 is provided.

The space 9 is provided so as not to impede vibrations of excitation regions C of the piezoelectric layer 2. Therefore, the support substrate 8 is laminated to the second principal surface 2b with the intermediate layer 7 interposed therebetween, at a position that does not overlap a portion where the at least one pair of electrode finger 3 and electrode finger 4 is provided. The intermediate layer 7 does not need to be provided. Therefore, the support substrate 8 can be laminated directly or indirectly on the second principal surface 2b of the piezoelectric layer 2.

The intermediate layer 7 is made of, for example, silicon oxide. The intermediate layer 7 may be made of an appropriate electrically insulating material, such as, for example, silicon nitride and alumina, other than silicon oxide.

The support substrate 8 is made of, for example, Si. A plane direction of a piezoelectric layer 2-side surface of Si may be (100) or (110) or may be (111). Preferably, high-resistance Si having a resistivity of, for example, higher than or equal to about 4 kΩ is preferable. The support substrate 8 may also be made of an appropriate electrically insulating material or an appropriate semiconductor material. Examples of the material of the support substrate 8 include a piezoelectric body, such as, for example, aluminum oxide, lithium tantalate, lithium niobate, and quartz crystal, various ceramics, such as alumina, magnesia, sapphire, silicon nitride, aluminum nitride, silicon carbide, zirconia, cordierite, mullite, steatite, and forsterite, a dielectric, such as diamond and glass, and a semiconductor, such as gallium nitride.

The plurality of electrode fingers 3, the plurality of electrode fingers 4, the first busbar electrode 5, and the second busbar electrode 6 are made of an appropriate metal or alloy, such as, for example, Al and AlCu alloy. In the present example embodiment, the electrode fingers 3, the electrode fingers 4, the first busbar electrode 5, and the second busbar electrode 6 include an Al film laminated on a Ti film, for example. An adhesion layer other than a Ti film may be used.

At the time of driving, an alternating-current voltage is applied between the plurality of electrode fingers 3 and the plurality of electrode fingers 4. More specifically, an alternating-current voltage is applied between the first busbar electrode 5 and the second busbar electrode 6. With this configuration, resonant characteristics that use bulk waves in the first thickness-shear mode, which are excited in the piezoelectric layer 2, can be obtained.

In the acoustic wave device 1, when the thickness of the piezoelectric layer 2 is d and the center-to-center distance between any adjacent electrode finger 3 and electrode finger 4 of the plurality of pairs of electrode finger 3 and electrode finger 4 is p, d/p is, for example, less than or equal to about 0.5. For this reason, bulk waves in the first thickness-shear mode are effectively excited, so good resonant characteristics are obtained. More preferably, for example, d/p is less than or equal to about 0.24, and, in this case, further good resonant characteristics are obtained.

When at least one of the electrode finger 3 and the electrode finger 4 is multiple as in the case of the present example embodiment, that is, when, where the electrode finger 3 and the electrode finger 4 are assumed as a paired electrode set, 1.5 or more pairs of the electrode finger 3 and the electrode finger 4 are provided, the center-to-center distance p between the adjacent electrode finger 3 and electrode finger 4 is an average distance of the center-to-center distances between any adjacent electrode finger 3 and electrode finger 4.

Since the acoustic wave device 1 of the present example embodiment has the above configuration, the quality factor is unlikely to decrease even when the number of pairs of the electrode finger 3 and the electrode finger 4 is reduced for the purpose of reducing the size. This is because the acoustic wave device 1 is a resonator that needs no reflectors on both sides and, therefore, a propagation loss is small. The reason why the reflector is not needed is because bulk waves in the first thickness-shear mode are used.

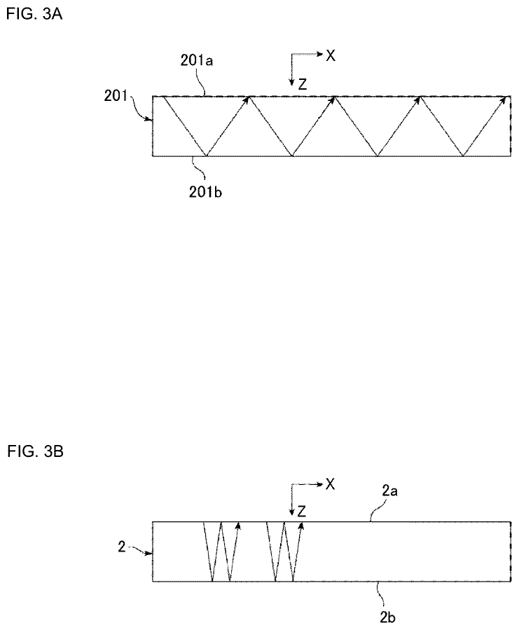

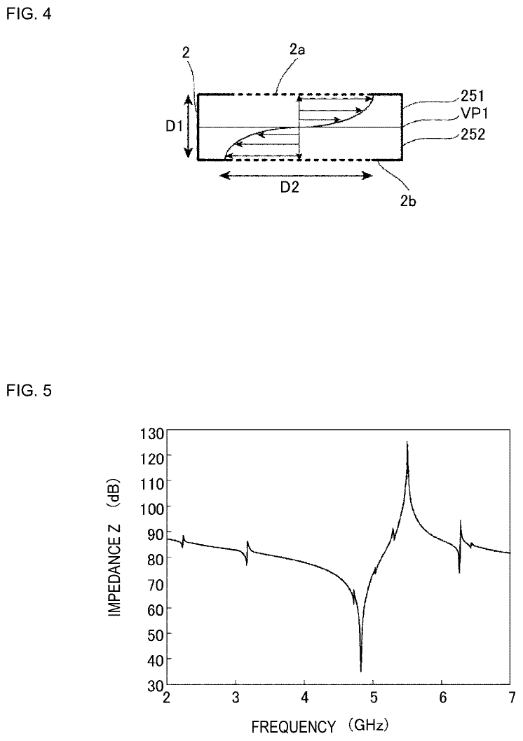

FIG. 3A is a schematic cross-sectional view for illustrating Lamb waves that propagate in a piezoelectric layer according to a comparative example. FIG. 3B is a schematic cross-sectional view for illustrating bulk waves in a first thickness-shear mode, which propagate in the piezoelectric layer according to the present example embodiment. FIG. 4 is a schematic cross-sectional view for illustrating bulk waves in a first thickness-shear mode in an amplitude direction, which propagate in the piezoelectric layer according to the present example embodiment.

FIG. 3A shows an acoustic wave device as described in Japanese Unexamined Patent Application Publication No. 2012-257019, and Lamb waves propagate in the piezoelectric layer. As shown in FIG. 3A, the waves propagate in a piezoelectric layer 201 as indicated by the arrows. Here, the piezoelectric layer 201 includes a first principal surface 201a and a second principal surface 201b, and a thickness direction connecting the first principal surface 201a and the second principal surface 201b is a Z direction. An X direction is a direction in which the electrode fingers 3, 4 of an interdigital transducer electrode are arranged. As shown in FIG. 3A, for Lamb waves, the waves propagate in the X direction as shown. The waves are plate waves, so the piezoelectric layer 201 vibrates as a whole. However, the waves propagate in the X direction. Therefore, resonant characteristics are obtained by arranging a reflector on each side. For this reason, a wave propagation loss occurs, and the quality factor decreases when the size is reduced, that is, when the number of pairs of electrode fingers 3, 4 is reduced.

In contrast, as shown in FIG. 3B, in the acoustic wave device according to the present example embodiment, a vibration displacement is caused in the thickness-shear direction, so the waves propagate substantially in the direction connecting the first principal surface 2a and the second principal surface 2b of the piezoelectric layer 2, that is, the Z direction, and resonate. In other words, the X-direction components of the waves are significantly smaller than the Z-direction components. Since the resonant characteristics are obtained from the propagation of the waves in the Z direction, no reflectors are needed. Thus, there is no propagation loss when the waves propagate to the reflectors. Therefore, even when the number of pairs of electrodes including the electrode fingers 3 and the electrode fingers 4 is reduced to reduce the size, the quality factor is unlikely to decrease.

As shown in FIG. 4, the amplitude direction of the bulk waves in the first thickness-shear mode is opposite between a first region 251 included in the excitation region C (see FIG. 1B) of the piezoelectric layer 2 and a second region 252 included in the excitation region C. FIG. 4 schematically shows bulk waves when a voltage with which the electrode fingers 4 are higher in potential than the electrode fingers 3 is applied between the electrode fingers 3 and the electrode fingers 4. The first region 251 is a region in the excitation region C between the first principal surface 2a and an imaginary plane VP1 that is orthogonal or substantially orthogonal to the thickness direction of the piezoelectric layer 2 and that divides the piezoelectric layer 2 into two. The second region 252 is a region in the excitation region C between the imaginary plane VP1 and the second principal surface 2b.

In the acoustic wave device 1, at least one pair of electrodes including the electrode finger 3 and the electrode finger 4 is disposed. However, the waves are not caused to propagate in the X direction, so the number of pairs of electrodes including the electrode finger 3 and the electrode finger 4 does not necessarily need to be multiple. In other words, at least one pair of electrodes may be provided.

For example, the electrode finger 3 is connected to a hot potential, and the electrode finger 4 is connected to a ground potential. The electrode finger 3 may be connected to a ground potential, and the electrode finger 4 may be connected to a hot potential. In the present example embodiment, each of the at least one pair of electrodes is an electrode connected to a hot potential or an electrode connected to a ground potential as described above, and no floating electrode is provided.

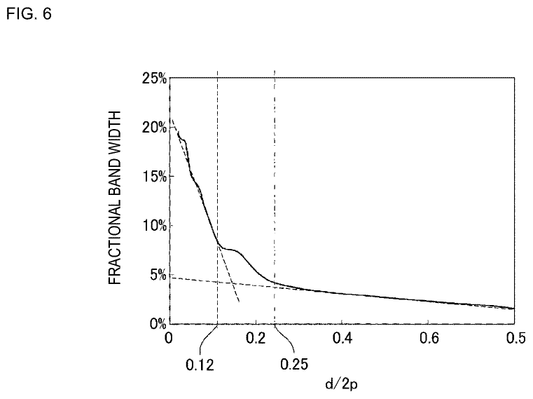

FIG. 5 is a graph that illustrates an example of the resonant characteristics of the acoustic wave device according to the present example embodiment. The design parameters of the acoustic wave device 1 having the resonant characteristics shown in FIG. 5 are as follows.

The piezoelectric layer 2 is made of LiNbO₃ with Euler angles of (0′, 0′, 90°). The thickness of the piezoelectric layer 2 is about 400 nm.

The length of the excitation region C (see FIG. 1B) is about 40 μm. The number of pairs of electrodes including the electrode fingers 3 and the electrode fingers 4 is 21. The center-to-center distance (pitch) between the electrode finger 3 and the electrode finger 4 is about 3 μm. The width of each of the electrode fingers 3 and the electrode fingers 4 is about 500 nm. d/p is about 0.133.

The intermediate layer 7 is made of a silicon oxide film having a thickness of about 1 μm.

The support substrate 8 is made of Si.

The excitation region C (see FIG. 1B) is a region in which the electrode finger 3 and the electrode finger 4 overlap each other when viewed in the X direction orthogonal or substantially orthogonal to the length direction of the electrode fingers 3 and electrode fingers 4. The length of the excitation region C is the dimension of the excitation region C along the length direction of the electrode fingers 3 and electrode fingers 4. Here, the excitation region C is an example of an overlap region.

In the present example embodiment, the distance between any adjacent electrodes of the pairs of electrodes consisting of the electrode fingers 3 and the electrode fingers 4 is equal or substantially equal among all of the plurality of pairs. In other words, the electrode fingers 3 and the electrode fingers 4 are disposed at a constant pitch.

As is apparent from FIG. 5, although no reflectors are provided, good resonant characteristics with a fractional band width of about 12.5% are obtained.

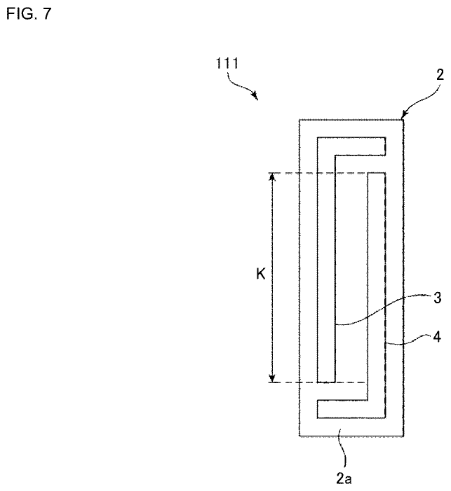

When the thickness of the piezoelectric layer 2 is d and the center-to-center distance between the electrodes of the electrode fingers 3 and the electrode fingers 4 is p, d/p is, for example, less than or equal to about 0.5 and preferably less than or equal to about 0.24 in the present example embodiment. This will be described with reference to FIG. 6.

A plurality of acoustic wave devices are obtained while d/2p is changed as in the case of the acoustic wave device having the resonant characteristics shown in FIG. 5. FIG. 6 is a graph that illustrates the relationship between d/2p and a fractional band width as a resonator where a center-to-center distance between adjacent electrodes or an average distance of center-to-center distances between the adjacent electrodes is p and an average thickness of the piezoelectric layer 2 is d in the acoustic wave device according to the first example embodiment.

As shown in FIG. 6, for example, when d/2p exceeds about 0.25, that is, d/p>about 0.5, the fractional band width is lower than about 5% even when d/p is adjusted. In contrast, in the case where d/2p≤about 0.25, that is, d/p≤about 0.5, d/p is changed within the range, the fractional band width can be set to about 5% or higher, that is, a resonator having a high coupling coefficient is provided. In the case where d/2p is lower than or equal to about 0.12, that is, d/p is less than or equal to about 0.24, the fractional band width can be increased to about 7% or higher. In addition, when d/p is adjusted within the range, a resonator having a further wide fractional band width is obtained, so a resonator having a further high coupling coefficient is achieved. Therefore, it was discovered and can be confirmed that, for example, when d/p is set to about 0.5 or less, a resonator that uses bulk waves in the first thickness-shear mode with a high coupling coefficient can be provided.

At least one pair of electrodes may be one pair, and, in the case of one pair of electrodes, p is defined as the center-to-center distance between the adjacent electrode finger 3 and electrode finger 4. In the case of 1.5 or more pairs of electrodes, an average distance of the center-to-center distances between any adjacent electrode finger 3 and electrode finger 4 just needs to be defined as p.

For the thickness d of the piezoelectric layer 2 as well, when the piezoelectric layer 2 has thickness variations, an averaged value of the thickness may be used.

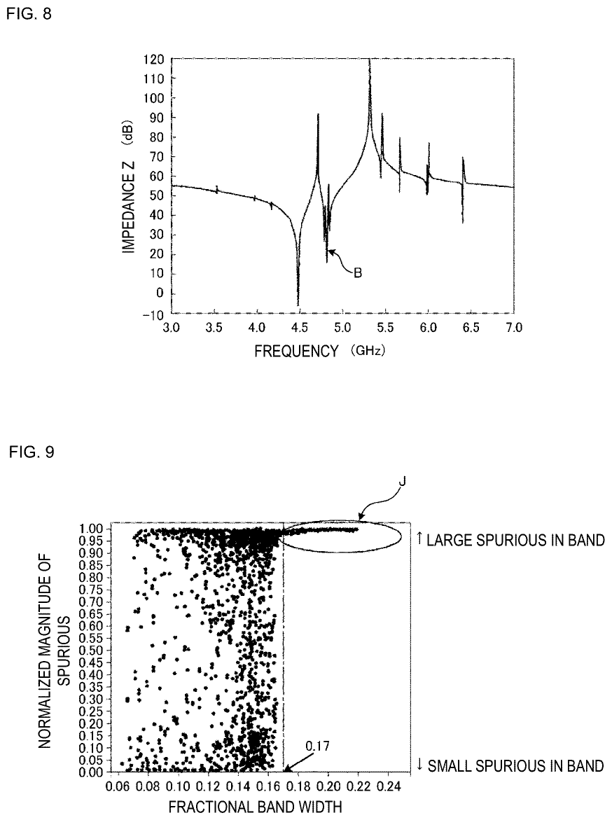

FIG. 7 is a plan view of an example in which a pair of electrodes is provided in an acoustic wave device according to the present example embodiment. In the acoustic wave device 101, one pair of electrodes including the electrode finger 3 and the electrode finger 4 is provided on the first principal surface 2a of the piezoelectric layer 2. In FIG. 7, K is an overlap width. As described above, in the acoustic wave device according to example embodiments of the present invention, the number of pairs of electrodes may be one. In this case as well, when d/p is, for example, less than or equal to about 0.5, bulk waves in the first thickness-shear mode can be effectively excited.

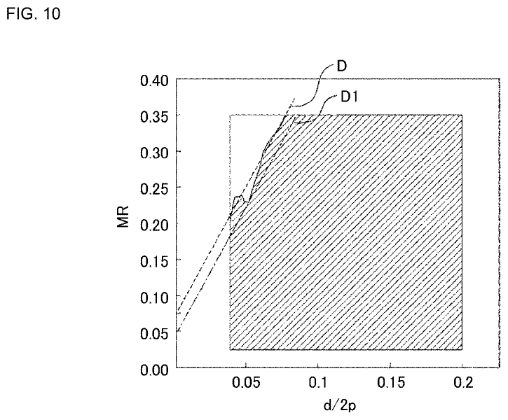

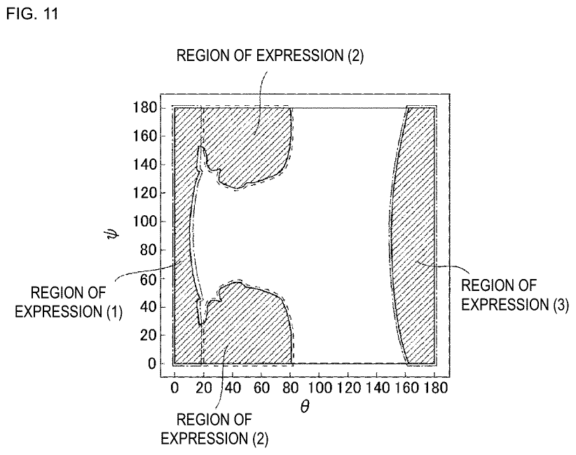

In the acoustic wave device 1, preferably, in the plurality of electrode fingers 3 and the plurality of electrode fingers 4, a metallization ratio MR of any adjacent electrode finger 3 and electrode finger 4 to the excitation region C that is a region in which the any adjacent electrode finger 3 and electrode finger 4 overlap each other when viewed in the opposed direction satisfy MR≤about 1.75(d/p)+0.075, for example. In this case, a spurious emission is effectively reduced. This will be described with reference to FIGS. 8 and 9.

FIG. 8 is a reference graph of an example of the resonant characteristics of the acoustic wave device according to the present example embodiment. The spurious emission indicated by the arrow B appears between a resonant frequency and an anti-resonant frequency. Here, d/p is set to about 0.08, and the Euler angles of LiNbO₃ were set to (0°, 0°, 90°). The metallization ratio MR was set to about 0.35, for example.

The metallization ratio MR will be described with reference to FIG. 1B. In the electrode structure of FIG. 1B, when focusing on one pair of electrode finger 3 and electrode finger 4, it is assumed that only the one pair of electrode finger 3 and electrode finger 4 is provided. In this case, the portion surrounded by the alternate long and short dashed line is an excitation region C. The excitation region C includes, when the electrode finger 3 and the electrode finger 4 are viewed in the direction orthogonal to the length direction of the electrode fingers 3 and electrode fingers 4, that is, the opposed direction, a region of the electrode finger 3, overlapping the electrode finger 4, a region of the electrode finger 4, overlapping the electrode finger 3, and a region in which the electrode finger 3 and the electrode finger 4 overlap each other in a region between the electrode finger 3 and the electrode finger 4. Then, the area of the electrode finger 3 and the electrode finger 4 in the excitation region C to the area of the excitation region C is a metallization ratio MR. In other words, the metallization ratio MR is the ratio of the area of a metallization portion to the area of the excitation region C.

When a plurality of pairs of electrode finger 3 and electrode finger 4 are provided, the ratio of a metallization portion included in all of the excitation regions C to the total area of the excitation regions C is set for MR.

FIG. 9 is a graph that illustrates the relationship between a fractional band width in the case where a large number of acoustic wave resonators are provided and a phase rotation amount of impedance of spurious normalized by about 180 degrees as the magnitude of a spurious emission in the acoustic wave device according to the present example embodiment. For fractional band width, the film thickness of the piezoelectric layer and the dimensions of the electrode fingers 3 and electrode fingers 4 were variously changed and adjusted. FIG. 9 is a result in the case where the piezoelectric layer 2 made of Z-cut LiNbO₃ is used, and similar tendency is obtained when a piezoelectric layer 2 with another cut angle is used as well.

In a region surrounded by the ellipse J in FIG. 9, the spurious emission is about 1.0 and large. As is apparent from FIG. 9, when the fractional band width exceeds about 0.17, that is, about 17%, a large spurious emission having a spurious level of greater than or equal to about one appears in a pass band even when parameters of the fractional band width are changed. In other words, as in the case of the resonant characteristics shown in FIG. 8, a large spurious emission indicated by the arrow B appears in the band. Thus, the fractional band width is preferably, for example, lower than or equal to about 17%. In this case, a spurious emission can be reduced by adjusting the film thickness of the piezoelectric layer 2, the dimensions of the electrode fingers 3 and electrode fingers 4, and the like.

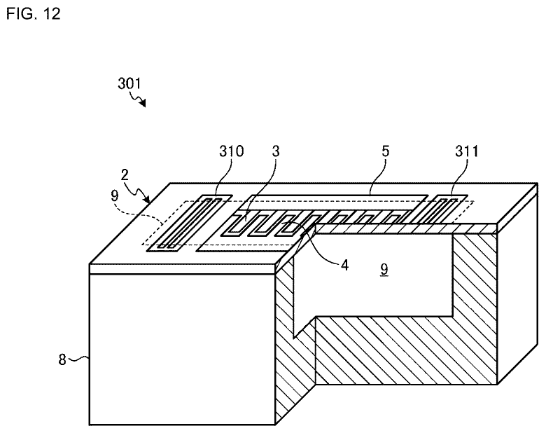

FIG. 10 is a graph that illustrates the relationship among d/2p, metallization ratio MR, and fractional band width. In the acoustic wave device 1 according to the present example embodiment, various acoustic wave devices 1 of which d/2p and MR were different were provided, and the fractional band widths were measured. The hatched portion to the right-hand side of the dashed line D in FIG. 10 is a region in which the fractional band width is lower than or equal to about 17%. A boundary between the hatched region and a non-hatched region is expressed by MR=about 3.5(d/2p)+0.075. In other words, MR=about 1.75(d/p)+0.075. Therefore, preferably, for example, MR≤about 1.75(d/p)+0.075. In this case, the fractional band width is easily set to about 17% or lower. More preferably, for example, this is the region to the right-hand side of MR=about 3.5(d/2p)+0.05 indicated by the alternate long and short dashed line D1 in FIG. 10. In other words, when MR≤about 1.75(d/p)+0.05, the fractional band width is reliably set to about 17% or lower.

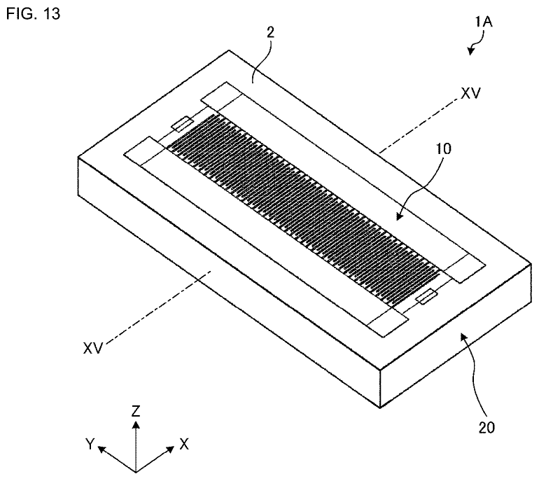

FIG. 11 is a diagram illustrating a map of a fractional band width for the Euler angles (0°, θ, ψ) of LiNbO₃ when d/p is brought close to zero without limit. The hatched portions in FIG. 11 are regions in which a fractional band width of at least about 5% or higher is obtained. When the range of the regions is approximated, the range is expressed by the following expression (1), expression (2), and expression (3).

(0°±10°,0° to 20°, any ψ) (1)

(0°±10°,20° to 80°,0° to 60° (1−(θ−50)²/900)^{1/2}) or (0°±10°,20° to 80°,[180°−60° (1−(θ−50)²/900)^{1/2}] to 180°) (2)

(0°±10°,[180°−30° (1−(ψ−90)²/8100)^{1/2}] to 180°, any ψ) (3)

Therefore, in the case of the range of Euler angles of the above expression (1), expression (2), or expression (3), the fractional band width is sufficiently widened, and it is preferable.

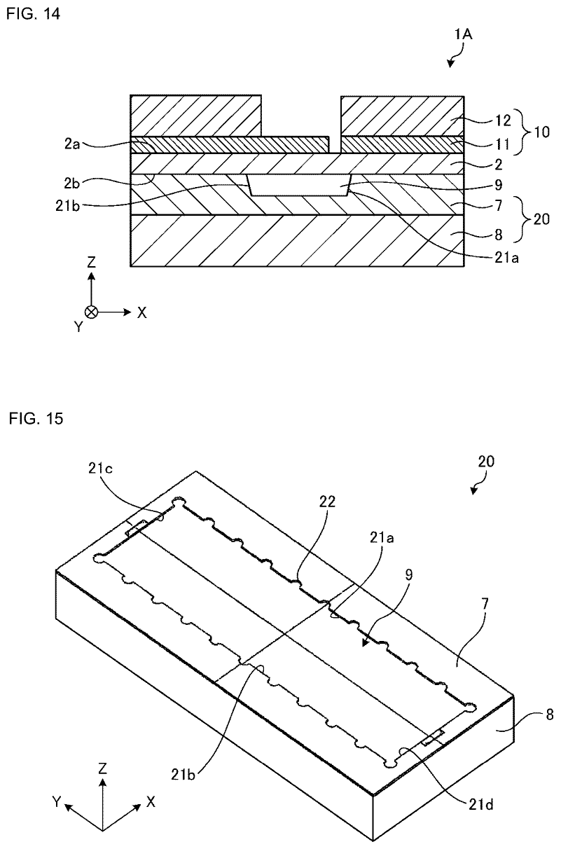

FIG. 12 is a partially cutaway perspective view for illustrating an acoustic wave device according to an example embodiment of the present invention. In FIG. 12, the outer periphery of the space 9 is indicated by dashed line. The acoustic wave device according to an example embodiment of the present invention may be configured to use plate waves. In this case, as shown in FIG. 12, the acoustic wave device 301 includes reflectors 310, 311. The reflectors 310, 311 are respectively provided on both sides of the electrode fingers 3, 4 on the piezoelectric layer 2 in an acoustic wave propagation direction. In the acoustic wave device 301, Lamb waves defining and functioning as plate waves are excited when an alternating-current electric field is applied to the electrode fingers 3, 4 above the space 9. Since the reflectors 310, 311 are respectively provided on both sides, resonant characteristics based on the Lamb waves defining and functioning as plate waves are obtained.

As described above, in the acoustic wave devices 1, 101, bulk waves in a first thickness-shear mode are used. In addition, in the acoustic wave devices 1, 101, the first electrode finger 3 and the second electrode finger 4 are adjacent electrodes, and, when the thickness of the piezoelectric layer 2 is d and the center-to-center distance between the first electrode finger 3 and the second electrode finger 4 is p, d/p is, for example, less than or equal to about 0.5. Thus, even when the size of the acoustic wave device reduces, the quality factor is improved.

In the acoustic wave devices 1, 101, the piezoelectric layer 2 is made of, for example, lithium niobate or lithium tantalate. The first electrode fingers 3 and the second electrode fingers 4, opposed in the direction that intersects with the thickness direction of the piezoelectric layer 2, are provided on the first principal surface 2a or second principal surface 2b of the piezoelectric layer 2. The first electrode fingers 3 and the second electrode fingers 4 are preferably covered with a protective film.

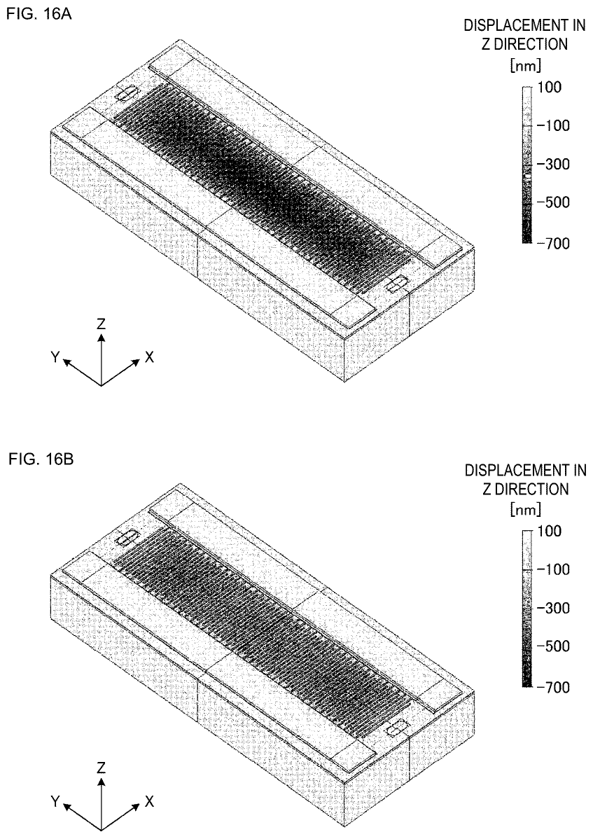

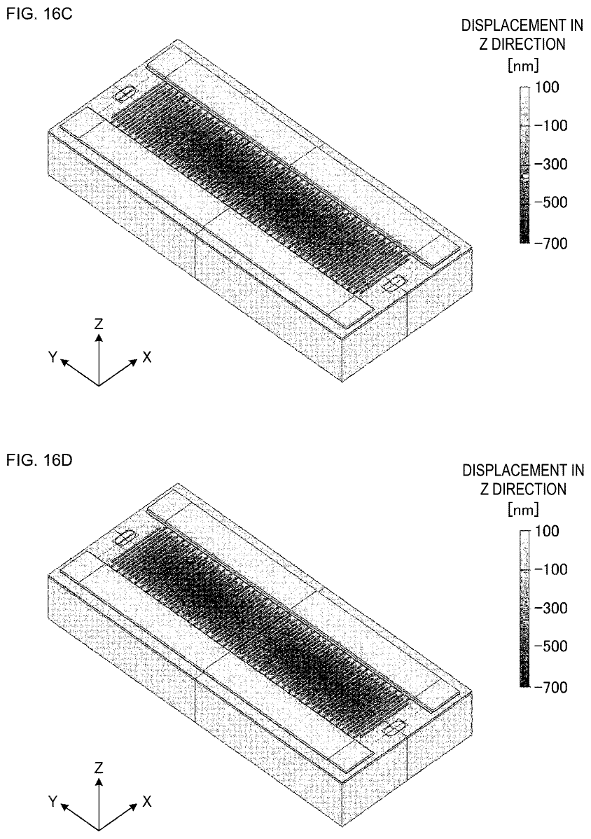

FIG. 13 is a perspective view of an example of the acoustic wave device according to the above-described example embodiment. FIG. 14 is a cross-sectional view taken along the line XV-XV in FIG. 13. In the following description, it is assumed that, of directions parallel or substantially parallel to the Z direction, one direction is an upward direction, and the other direction is a downward direction. As shown in FIG. 13, an acoustic wave device 1A according to an example embodiment includes a functional electrode 10, a support 20, and the piezoelectric layer 2.

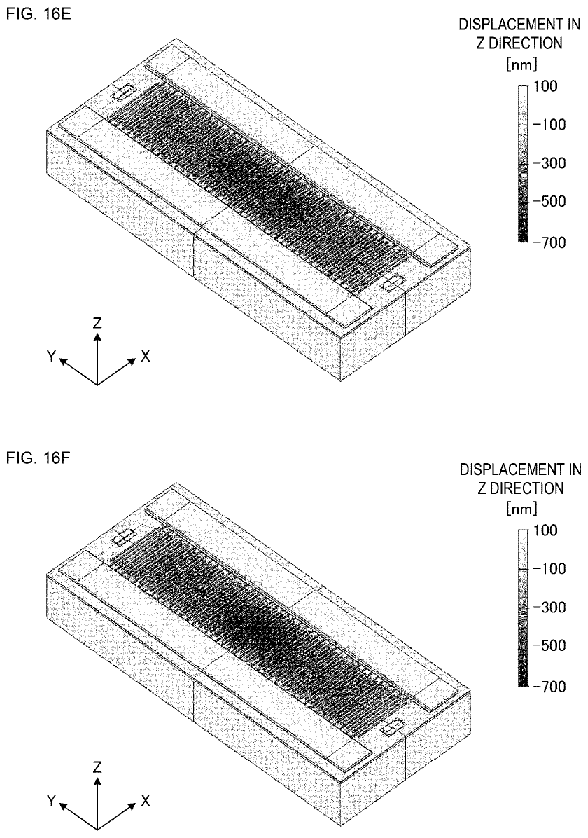

The functional electrode 10 is an electrode provided on the piezoelectric layer 2. In the example of FIGS. 14 and 15, the functional electrode 10 is provided on the first principal surface 2a of the piezoelectric layer 2. The functional electrode 10 includes a wiring electrode and an interdigital transducer electrode. The wiring electrode connects a resonator including the interdigital transducer electrode with another element. In the example of FIG. 15, the functional electrode 10 includes a first metal layer 11 and a second metal layer 12.

The first metal layer 11 is provided on the piezoelectric layer 2. In the example of FIG. 14, the first metal layer 11 defines the electrode fingers 3, 4 and the busbar electrodes 5, 6. The first metal layer 11 includes, for example, aluminum (Al). Thus, good frequency characteristics are obtained. The first metal layer 11 is not limited to being made of an elemental metal and may be an alloy. The first metal layer 11 is not limited to being provided so as to be in contact with the first principal surface 2a of the piezoelectric layer 2. The first metal layer 11 may be laminated on the piezoelectric layer 2 with a layer interposed therebetween. The layer is made of, for example, a material different from the material of the first metal layer 11, that is, titanium (Ti), chromium (Cr), or the like.

The second metal layer 12 is laminated on at least a portion of the first metal layer 11. In the example of FIG. 14, the second metal layer 12 defines the wiring electrode. The second metal layer 12 is preferably made of a metal having a small electrical resistance and a smaller coefficient of linear expansion than the first metal layer 11. The second metal layer 12 preferably includes, for example, gold (Au) or copper (Cu). Thus, the first metal layer 11 is supported by the second metal layer 12 having a smaller coefficient of linear expansion than the first metal layer 11, so warpage of the piezoelectric layer 2 is further reduced or prevented. The second metal layer 12 is not limited to being made of an elemental metal and may be an alloy.

The support 20 includes the support substrate 8. The support 20 is provided under the piezoelectric layer 2. In the present example embodiment, the support 20 includes the intermediate layer 7 and the support substrate 8. The support 20 includes the space 9 in a region in which the support 20 at least partially overlaps the space 9 in a plan view in the Z direction. In the example of FIG. 14, the space 9 is provided on a side of the intermediate layer 7 in the Z direction where the piezoelectric layer 2 is provided. The space 9 may extend through the intermediate layer 7 or may be provided in the intermediate layer 7 and the support substrate 8.

FIG. 15 is a perspective view of the support of the acoustic wave device shown in FIG. 13. As shown in FIG. 15, the support 20 includes inner walls 21. The inner walls 21 are wall surfaces excluding surfaces parallel or substantially parallel to an X-Y plane, of the surfaces of the support 20, exposed to the space 9. In the present example embodiment, the inner wall 21 includes two inner walls 21a, 21b opposed in the X direction and two inner walls 21c, 21d opposed in the Y direction. Notches 22 are provided on the inner walls 21.

The notches 22 are recesses provided on the inner walls 21. In other words, a space in each notch 22 communicates with the space 9. In the example of FIG. 15, at least one notch 22 is provided on each of the two inner walls 21a, 21b opposed in the X direction. Thus, the notches 22 absorb the stress of the piezoelectric layer 2, so it is possible to reduce or prevent warpage of the piezoelectric layer 2.

The notches 22 are provided so as not to overlap the excitation regions C in a plan view in the Z direction. In the example of FIG. 15, the notches 22 are provided so as to at least partially overlap the busbar electrodes 5, 6 in a plan view in the Z direction. Thus, it is possible to reduce or prevent impairment of the operations of the electrode fingers 3, 4 by the notches 22. In the example of FIG. 15, the notch 22 is provided near the center of each of the inner walls 21a, 21b in the Y direction. Thus, since the notches 22 are provided at locations in the Y direction where the piezoelectric layer 2 is easily warped the most, it is possible to further reduce or prevent warpage of the piezoelectric layer 2.

The width of each notch 22 is greater than or equal to about 1 μm, for example. Thus, stress can be sufficiently absorbed, with the result that warpage of the piezoelectric layer 2 is reduced or prevented. The width of each notch 22 is less than or equal to about 30 μm, for example. Thus, machining is facilitated. Here, the width of the notch 22 means the maximum length of the notch 22 in a direction in which the inner walls 21a, 21b provided with the notches 22 extend in a plan view in the Z direction. The shape of the notch 22 is a circular or substantially circular shape in a plan view in the Z direction and is merely an example. Alternatively, the shape of the notch 22 may be a rectangular or substantially rectangular shape, a triangular or substantially triangular shape, or the like, for example.

The notches 22 are provided adjacent to, of ends opposed in the Z direction of each of the inner walls 21a, 21b, a side where at least the piezoelectric layer 2 is provided. In FIG. 15, the notch 22 has a cylindrical shape extending in the Z direction, and the maximum depth of the notch 22 is the same or substantially the same as the depth of the space 9. Here, the depth of the space 9 means a distance in the Z direction from a surface that is in contact with the piezoelectric layer 2 to a surface exposed to the space 9, of surfaces parallel or substantially parallel to an X-Y plane of the support 20. The maximum depth of the notch 22 may be less than the depth of the space 9. In other words, the notch 22 may have a shape obtained by hollowing the inner wall 21 in a cup shape.

In the example of FIG. 15, the notches 22 are provided at intervals along the inner walls 21. In other words, a plurality of the notches 22 are provided on one inner wall 21a. Here, of the two inner walls 21a, 21b opposed in the X direction, the number of notches 22 provided on one inner wall 21a is equal to the number of notches 22 provided on the other inner wall 21b. In the example of FIG. 15, the plurality of notches 22 provided on one inner wall 21a is provided symmetrically or substantially symmetrically with respect to the center of the inner wall 21a in the Y direction. An array of the plurality of notches 22 is not limited to the one shown in FIG. 15 and may be provided asymmetrically with respect to the center of the inner wall 21a in the Y direction. The plurality of notches 22 do not need to be provided at constant intervals and may include a notch having a different size or shape.

The acoustic wave device 1A according to the first example embodiment has been described above; however, the acoustic wave device according to the first example embodiment is not limited thereto. For example, the intermediate layer 7 is not an indispensable component, and the piezoelectric layer 2 may be provided on the support substrate 8. The functional electrode 10 does not need to include the first metal layer 11 and the second metal layer 12 and may include a single metal.

Hereinafter, test examples will be described. As test examples of the acoustic wave device 1A according to the present example embodiment, simulation models were created with the following design parameters.

The piezoelectric layer 2 is made of, for example, LiNbO₃ with Euler angles of (0°, 37.5°, 0°). The thickness of the piezoelectric layer 2 is, for example, about 385 nm. The support substrate 8 is made of, for example, Si. The thickness of the support substrate 8 is, for example, about 50 μm. The intermediate layer 7 is made of, for example silicon oxide. The thickness of the intermediate layer 7 is, for example, about 2 μm. The depth (length in the Z direction) of the space 9 is, for example, about 1.5 μm. The first metal layer 11 is made of, for example, Al. The thickness of the first metal layer 11 is, for example, about 504 nm. The thickness of the second metal layer 12 is, for example, about 2.9 μm.

Table 1 shows Comparative Examples and Examples according to the present example embodiment. In simulations, as shown in Table 1, for acoustic wave devices according to Comparative Example 1 to Comparative Example 3 and Test Example 1 to Test Example 15, among which the material of the second metal layer 12 and the number of the notches 22 per one inner wall were changed, a displacement in the Z direction of the piezoelectric layer 2 in the case where the temperature of the piezoelectric layer 2 was about 105° C. was calculated.

TABLE 1

| | MATERIAL | NUMBER OF |
|---|---|---|
| | OF SECOND | NOTCHES PER |
| TEST EXAMPLE | METAL LAYER | INNER WALL |
| COMPARATIVE EXAMPLE 1 | Al | 0 |
| EXAMPLE 1 | Al | 1 |
| EXAMPLE 2 | Al | 3 |
| EXAMPLE 3 | Al | 5 |
| EXAMPLE 4 | Al | 7 |
| EXAMPLE 5 | Al | 11 |
| COMPARATIVE EXAMPLE 2 | Cu | 0 |
| EXAMPLE 6 | Cu | 1 |
| EXAMPLE 7 | Cu | 3 |
| EXAMPLE 8 | Cu | 5 |
| EXAMPLE 9 | Cu | 7 |
| EXAMPLE 10 | Cu | 11 |
| COMPARATIVE EXAMPLE 3 | Au | 0 |
| EXAMPLE 11 | Au | 1 |
| EXAMPLE 12 | Au | 3 |
| EXAMPLE 13 | Au | 5 |
| EXAMPLE 14 | Au | 7 |
| EXAMPLE 15 | Au | 11 |

Hereinafter, simulation results of the acoustic wave devices according to Comparative Example 1 to Comparative Example 3 and Test Example 1 to Test Example 15 will be described with reference to the drawings. In the following description, the description may be made on the assumption that a distance from the center of the space 9 in the Y direction is a location in the Y direction. The description may be made on the assumption that the average of a displacement in the Z direction along the line A-A′ of a region of the piezoelectric layer 2, which overlaps the space 9 in a plan view in the Z direction, is an average of a displacement in the Z direction along the line A-A′ in FIG. 13 of the piezoelectric layer 2.

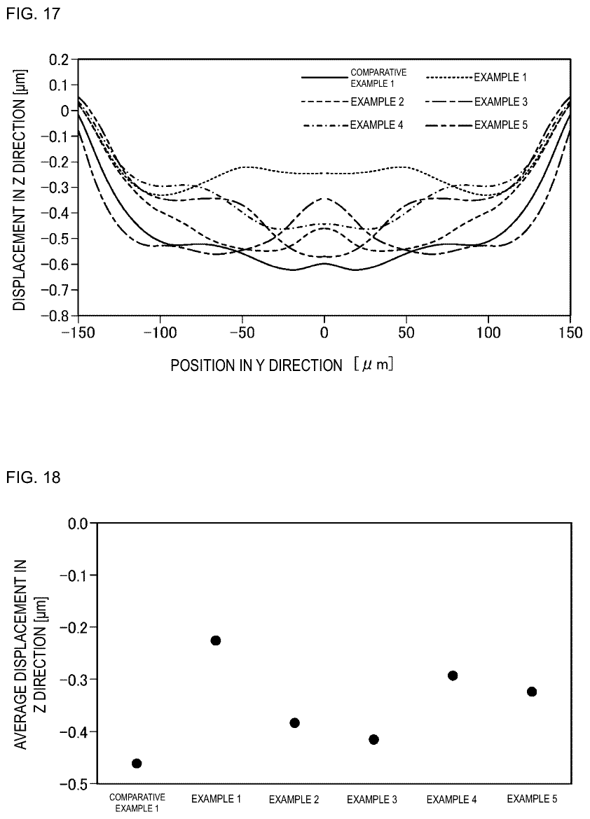

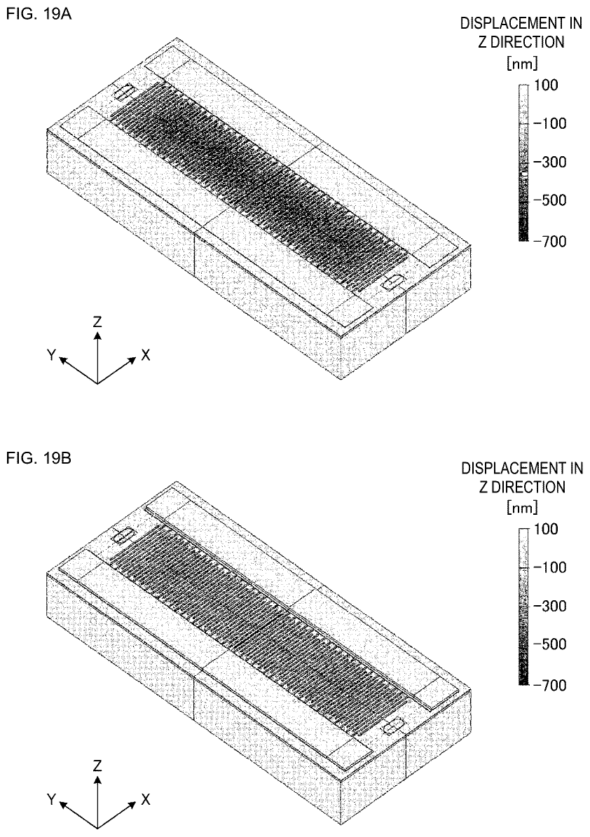

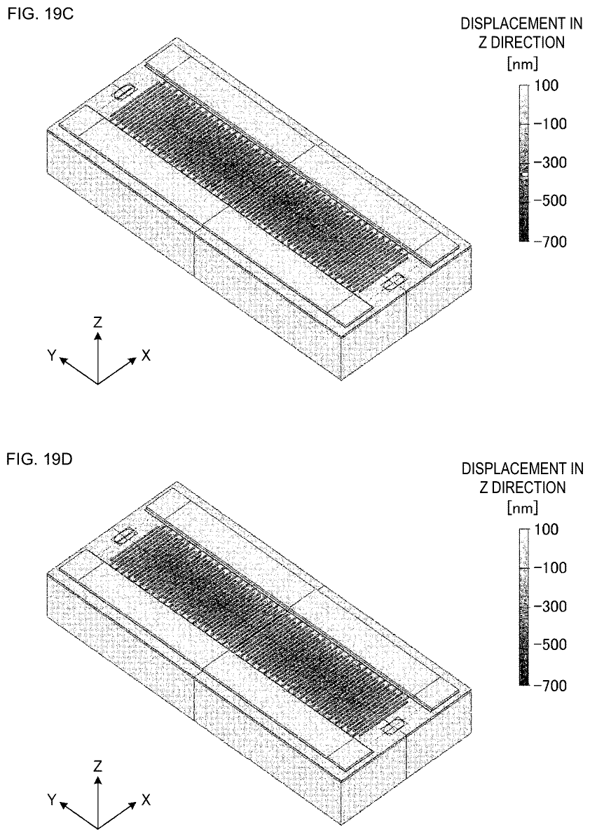

FIG. 16A is a view that shows a distribution of displacement in the Z direction of the piezoelectric layer of the acoustic wave device according to Comparative Example 1. FIG. 16B is a view that shows a distribution of displacement in the Z direction of the piezoelectric layer of the acoustic wave device according to Example 1. FIG. 16C is a view that shows a distribution of displacement in the Z direction of the piezoelectric layer of the acoustic wave device according to Example 2. FIG. 16D is a view that shows a distribution of displacement in the Z direction of the piezoelectric layer of the acoustic wave device according to Example 3. FIG. 16E is a view that shows a distribution of displacement in the Z direction of the piezoelectric layer of the acoustic wave device according to Example 4. FIG. 16F is a view that shows a distribution of displacement in the Z direction of the piezoelectric layer of the acoustic wave device according to Example 5. FIG. 17 is a graph that shows a displacement in the Z direction along the A-A′ line in FIG. 13 of each of the piezoelectric layers of the acoustic wave devices according to Comparative Example 1 and Example 1 to Example 5. FIG. 18 is a graph that shows an average value of displacement in the Z direction along the A-A′ line in FIG. 13 of each of the piezoelectric layers of the acoustic wave devices according to Comparative Example 1 and Example 1 to Example 5. In Comparative Example 1, as shown in FIGS. 16A and 18, a displacement in the Z direction of the piezoelectric layer 2 is large near the center of the space 9 in the Y direction, and there is a portion where the piezoelectric layer 2 excessively warps. On the other hand, in Example 1 to Example 5, as shown in FIGS. 16B to 16F, and 18, as compared to Comparative Example 1, a displacement of the piezoelectric layer 2 in the Z direction is small, and warpage of the piezoelectric layer 2 near the center of the space 9 in the Y direction is reduced or prevented. Thus, it appears that warpage of the piezoelectric layer 2 is reduced or prevented with the notches 22 on the inner walls 21. As shown in FIG. 17, in Example 1 to Example 5, warpage of the piezoelectric layer 2 near the center of the space 9 in the Y direction is reduced or prevented. Thus, it appears that warpage in a region in which warpage of the piezoelectric layer 2 easily occurs is reduced or prevented.

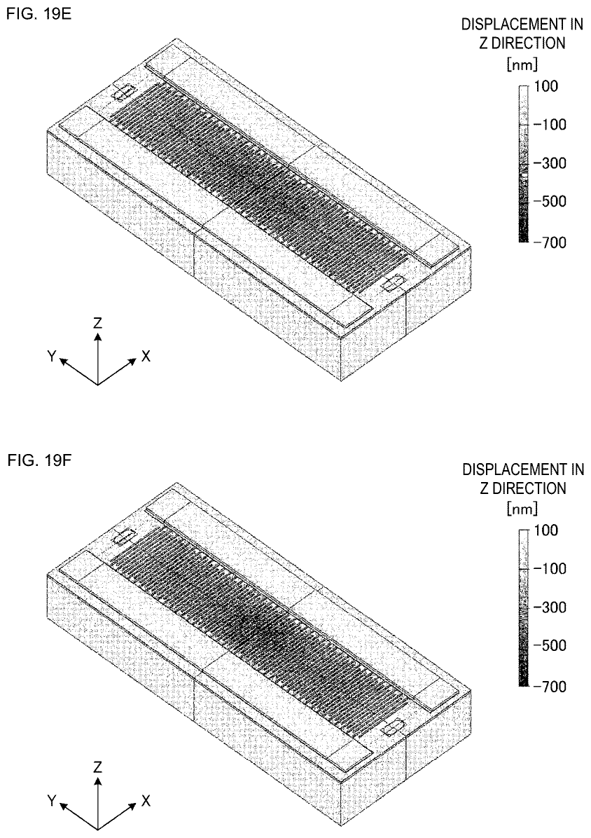

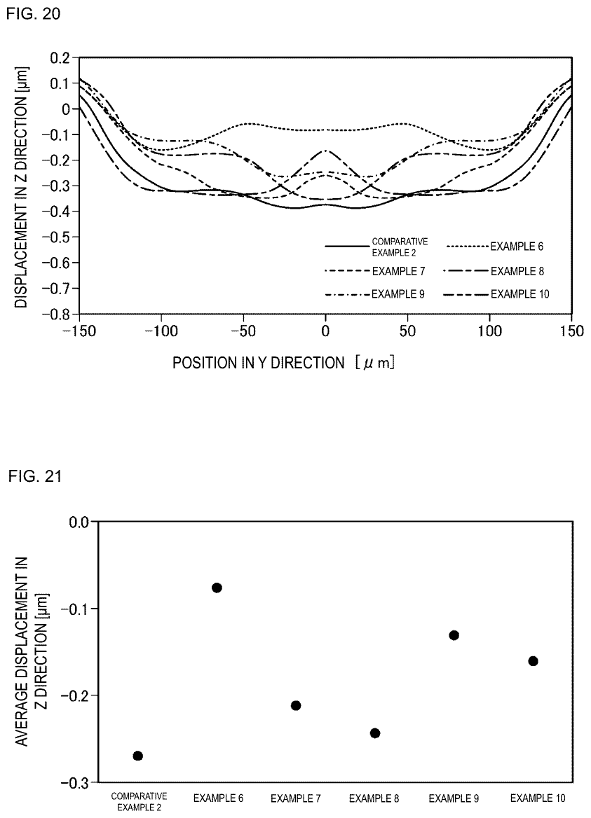

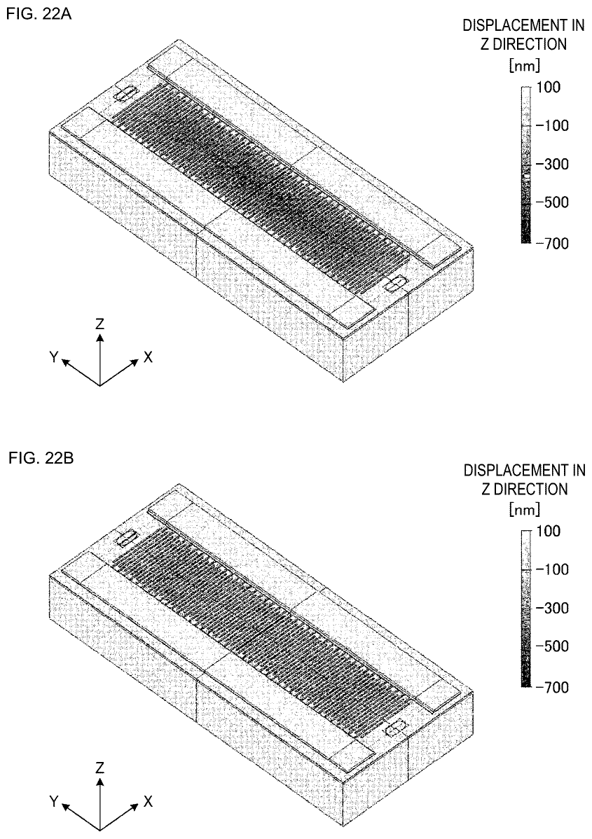

FIG. 19A is a view that shows a distribution of displacement in the Z direction of the piezoelectric layer of the acoustic wave device according to Comparative Example 2. FIG. 19B is a view that shows a distribution of displacement in the Z direction of the piezoelectric layer of the acoustic wave device according to Example 6. FIG. 19C is a view that shows a distribution of displacement in the Z direction of the piezoelectric layer of the acoustic wave device according to Example 7. FIG. 19D is a view that shows a distribution of displacement in the Z direction of the piezoelectric layer of the acoustic wave device according to Example 8. FIG. 19E is a view that shows a distribution of displacement in the Z direction of the piezoelectric layer of the acoustic wave device according to Example 9. FIG. 19F is a view that shows a distribution of displacement in the Z direction of the piezoelectric layer of the acoustic wave device according to Example 10. FIG. 20 is a graph that shows a displacement in the Z direction along the A-A′ line in FIG. 13 of each of the piezoelectric layers of the acoustic wave devices according to Comparative Example 2 and Example 6 to Example 10. FIG. 21 is a graph that shows an average value of displacement in the Z direction along the A-A′ line in FIG. 13 of each of the piezoelectric layers of the acoustic wave devices according to Comparative Example 2 and Example 6 to Example 10. In Comparative Example 2, as shown in FIGS. 19A and 20, a displacement in the Z direction of the piezoelectric layer 2 is large near the center of the space 9 in the Y direction, and there is a portion where the piezoelectric layer 2 excessively warps. On the other hand, in Example 6 to Example 10, as shown in FIGS. 19B to 19F, and 21, as compared to Comparative Example 2, a displacement of the piezoelectric layer 2 in the Z direction is small, and warpage of the piezoelectric layer 2 near the center of the space 9 in the Y direction is reduced or prevented. Thus, it appears that warpage of the piezoelectric layer 2 is reduced or prevented with the notches 22 on the inner walls 21. As shown in FIG. 20, in Example 6 to Example 10, warpage of the piezoelectric layer 2 near the center of the space 9 in the Y direction is reduced or prevented. Thus, it appears that warpage in a region in which warpage of the piezoelectric layer 2 easily occurs is reduced or prevented.

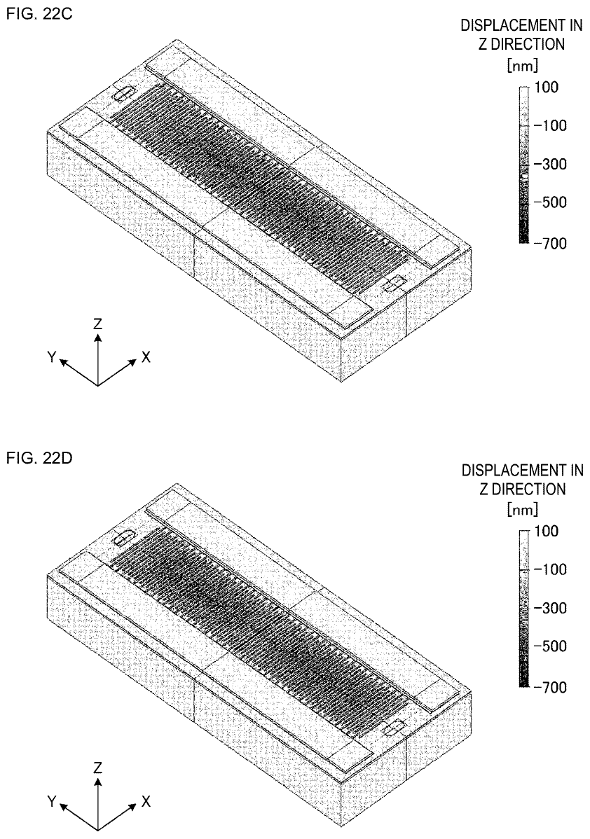

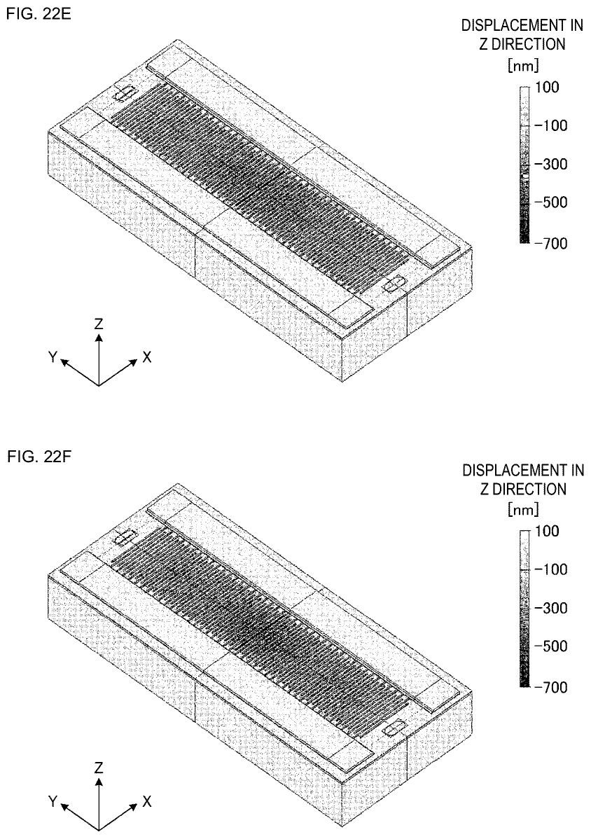

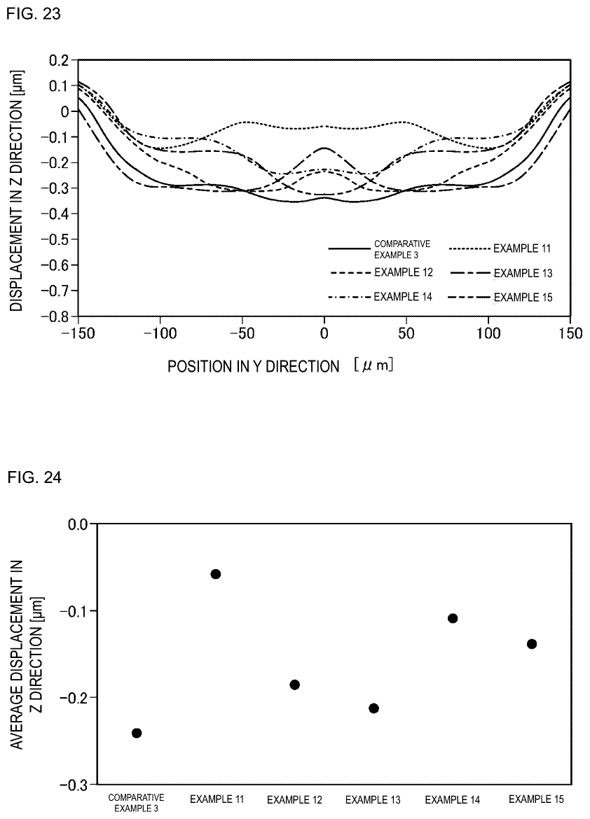

FIG. 22A is a view that shows a distribution of displacement in the Z direction of the piezoelectric layer of the acoustic wave device according to Comparative Example 3. FIG. 22B is a view that shows a distribution of displacement in the Z direction of the piezoelectric layer of the acoustic wave device according to Example 11. FIG. 22C is a view that shows a distribution of displacement in the Z direction of the piezoelectric layer of the acoustic wave device according to Example 12. FIG. 22D is a view that shows a distribution of displacement in the Z direction of the piezoelectric layer of the acoustic wave device according to Example 13. FIG. 22E is a view that shows a distribution of displacement in the Z direction of the piezoelectric layer of the acoustic wave device according to Example 14. FIG. 22F is a view that shows a distribution of displacement in the Z direction of the piezoelectric layer of the acoustic wave device according to Example 15. FIG. 23 is a graph that shows a displacement in the Z direction along the A-A′ line in FIG. 13 of each of the piezoelectric layers of the acoustic wave devices according to Comparative Example 3 and Example 11 to Example 15. FIG. 24 is a graph that shows an average value of displacement in the Z direction along the A-A′ line in FIG. 13 of each of the piezoelectric layers of the acoustic wave devices according to Comparative Example 3 and Example 11 to Example 15. In Comparative Example 3, as shown in FIGS. 22A and 23, a displacement in the Z direction of the piezoelectric layer 2 is large near the center of the space 9 in the Y direction, and there is a part where the piezoelectric layer 2 excessively warps. On the other hand, in Example 11 to Example 15, as shown in FIGS. 22B to 22F, and 24, as compared to Comparative Example 3, a displacement of the piezoelectric layer 2 in the Z direction is small, and warpage of the piezoelectric layer 2 near the center of the space 9 in the Y direction is reduced or prevented. Thus, it appears that warpage of the piezoelectric layer 2 is reduced or prevented with the notches 22 on the inner walls 21. As shown in FIG. 23, in Example 11 to Example 15, warpage of the piezoelectric layer 2 near the center of the space 9 in the Y direction is reduced or prevented. Thus, it appears that warpage in a region in which warpage of the piezoelectric layer 2 easily occurs is reduced or prevented.

As described above, an acoustic wave device according to an example embodiment includes a support substrate 8 having a thickness in a first direction, an intermediate layer 7 provided on the support substrate 8, a piezoelectric layer 2 provided on the intermediate layer 7, and an interdigital transducer electrode including a first electrode finger 3 provided on a principal surface of the piezoelectric layer 2 and extending in a second direction that intersects with the first direction, a first busbar electrode 5 to which the first electrode finger 3 is connected, a second electrode finger 4 opposed to the first electrode finger 3 in a third direction orthogonal or substantially orthogonal to the second direction and extending in the second direction, and a second busbar electrode 6 to which the second electrode finger 4 is connected. The intermediate layer 7 includes a space 9 in a region in which at least a portion of the intermediate layer 7 overlaps the interdigital transducer electrode in a plan view in the first direction, and an inner wall 21 of the space 9 of the intermediate layer 7 includes at least one notch 22. Thus, the notch 22 absorbs the stress of the piezoelectric layer 2, so it is possible to reduce or prevent warpage of the piezoelectric layer 2.

An acoustic wave device according to an example embodiment includes a support substrate 8 with a thickness in a first direction, a piezoelectric layer 2 on the support substrate 8, and an interdigital transducer electrode including a first electrode finger 3 on a principal surface of the piezoelectric layer 2 and extending in a second direction that intersects with the first direction, a first busbar electrode 5 to which the first electrode finger 3 is connected, a second electrode finger 4 opposed to any one of the first electrode finger 3 in a third direction orthogonal or substantially orthogonal to the second direction and extending in the second direction, and a second busbar electrode 6 to which the second electrode finger 4 is connected. The support substrate 8 includes a space 9 in a region in which at least a portion of the support substrate 8 overlaps the interdigital transducer electrode in a plan view in the first direction, and an inner wall 21 of the space 9 includes at least one notch 22. Thus, the at least one notch 22 absorbs the stress of the piezoelectric layer 2, so it is possible to reduce or prevent warpage of the piezoelectric layer 2.

In an example embodiment, the notch 22 does not overlap an overlap region (excitation region C) in which the first electrode finger 3 and the second electrode finger 4 overlap each other when viewed in the third direction in a plan view in the first direction. Thus, it is possible to reduce or prevent impairment of the operations of the electrode fingers 3, 4 by the notch 22.

The intermediate layer 7 may include silicon oxide. In this case, a difference between the piezoelectric layer 2 and the intermediate layer 7 increases, so the piezoelectric layer 2 easily warps. For this reason, with the notch 22, it is possible to further effectively reduce or prevent warpage of the piezoelectric layer 2.

The support substrate 8 may include Si. In this case, a difference between the piezoelectric layer 2 and the support substrate 8 increases, so the piezoelectric layer 2 easily warps. For this reason, with the notch 22, it is possible to further effectively reduce or prevent warpage of the piezoelectric layer 2.

A plurality of the notches 22 may be provided at intervals along the inner wall 21 of the space 9. In this case as well, it is possible to reduce or prevent warpage of the piezoelectric layer 2.

In an example embodiment, of the four inner walls 21 of the space 9, the notch 22 is provided on each of the opposed two inner walls 21, and a number of notches 22 provided on one of the two inner walls 21 is equal to a number of notches 22 provided on the other one of the two inner walls 21. In this case as well, it is possible to reduce or prevent warpage of the piezoelectric layer 2.

A thickness of the piezoelectric layer 2 in the first direction may be less than or equal to about 1 μm. In this case as well, it is possible to reduce or prevent warpage of the piezoelectric layer 2.

In an example embodiment, where, of the first electrode finger 3 and the second electrode finger 4, a center-to-center distance between adjacent two of the first electrode finger 3 and the second electrode finger 4 is p, a thickness of the piezoelectric layer 2 is less than or equal to about 2p. Thus, the size of the acoustic wave device 1 is reduced, and the quality factor is improved.

In an example embodiment, the piezoelectric layer 2 may include lithium niobate or lithium tantalate. Thus, the acoustic wave device with which good resonant characteristics are obtained is provided.

In an example embodiment, the acoustic wave device may be structured to generate bulk waves in a thickness-shear mode. Thus, a coupling coefficient increases, so the acoustic wave device with which good resonant characteristics are obtained is provided.

In an example embodiment, where a thickness of the piezoelectric layer 2 is d and a center-to-center distance between adjacent two of the first electrode finger 3 and the second electrode finger 4 is p, d/p may be less than or equal to about 0.5. Thus, the size of the acoustic wave device 1 is reduced, and the quality factor is improved.

In an example embodiment, d/p may be less than or equal to about 0.24. Thus, the size of the acoustic wave device 1 is reduced, and the quality factor is improved.

In an example embodiment, a region in which the first electrode finger 3 and the second electrode finger 4 overlap each other when viewed in the third direction is an excitation region C, and, where a metallization ratio of the first electrode finger 3 and the second electrode finger 4 to the excitation region C is MR, MR≤about 1.75(d/p)+0.075 may be satisfied. In this case, the fractional band width is reliably set to about 17% or lower.

In an example embodiment, the acoustic wave device may be structured to generate plate waves. Thus, the acoustic wave device with which good resonant characteristics are obtained is provided.

In an example embodiment, Euler angles (φ, θ, ψ) of the lithium niobate or the lithium tantalate fall within a range of the following expression (1), expression (2), or expression (3). In this case, a fractional band width is sufficiently widened.

(0°±10°,0° to 20°, any ψ) (1)

(0°±10°,20° to 80°,0° to 60° (1−(0−50)²/900)^{1/2}) or (0°±10°,20° to 80°,[180°−60° (1−(0−50)²/900)^{1/2}] to 180°) (2)

(0°±10°,[180°−30° (1−(ψ−90)²/8100)^{1/2}] to 180°, any ψ) (3)

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a support substrate with a thickness in a first direction;
an intermediate layer on the support substrate;
a piezoelectric layer on the intermediate layer; and
an interdigital transducer electrode including a first electrode finger on a principal surface of the piezoelectric layer and extending in a second direction that intersects with the first direction, a first busbar electrode connected to the first electrode finger, a second electrode finger opposed to the first electrode finger in a third direction orthogonal or substantially orthogonal to the second direction and extending in the second direction, and a second busbar electrode connected to the second electrode finger; wherein
the intermediate layer in a space in a region in which at least a portion of the intermediate layer overlaps the interdigital transducer electrode in a plan view in the first direction; and
an inner wall of the space includes at least one notch.

2. An acoustic wave device comprising:
a support substrate with a thickness in a first direction;
a piezoelectric layer on the support substrate; and
an interdigital transducer electrode including a first electrode finger on a principal surface of the piezoelectric layer and extending in a second direction that intersects with the first direction, a first busbar electrode connected to the first electrode finger, a second electrode finger opposed to the first electrode finger in a third direction orthogonal or substantially orthogonal to the second direction and extending in the second direction, and a second busbar electrode connected to the second electrode finger; wherein
the support substrate includes a space in a region in which at least a portion of the support substrate overlaps the interdigital transducer electrode in a plan view in the first direction; and
an inner wall of the space includes at least one notch.

3. The acoustic wave device according to claim 1, wherein the notch does not overlap an overlap region in a plan view in the first direction, and the first electrode finger and the second electrode finger overlap each other in the overlap region when viewed in the third direction.

4. The acoustic wave device according to claim 2, wherein the notch does not overlap an overlap region in a plan view in the first direction, and the first electrode finger and the second electrode finger overlap each other in the overlap region when viewed in the third direction.

5. The acoustic wave device according to claim 1, wherein the intermediate layer includes silicon oxide.

6. The acoustic wave device according to claim 1, wherein the support substrate includes Si.

7. The acoustic wave device according to claim 2, wherein the support substrate includes Si.

8. The acoustic wave device according to claim 1, wherein a plurality of the notches are provided at intervals along the inner wall of the space.

9. The acoustic wave device according to claim 2, wherein a plurality of the notches are provided at intervals along the inner wall of the space.

10. The acoustic wave device according to claim 1, wherein
of four inner walls of the space, the notch is on each of opposed two inner walls; and
a number of notches on one of the two inner walls is equal to a number of notches on the other one of the two inner walls.

11. The acoustic wave device according to claim 2, wherein
of four inner walls of the space, the notch is on each of opposed two inner walls; and
a number of notches on one of the two inner walls is equal to a number of notches on the other one of the two inner walls.

12. The acoustic wave device according to claim 1, wherein a thickness of the piezoelectric layer in the first direction is less than or equal to about 1 μm.

13. The acoustic wave device according to claim 1, wherein a thickness of the piezoelectric layer is less than or equal to about 2p, where of the first electrode finger and the second electrode finger, a center-to-center distance between adjacent two of the first electrode finger and the second electrode finger is p.

14. The acoustic wave device according to claim 1, wherein the piezoelectric layer includes lithium niobate or lithium tantalate.

15. The acoustic wave device according to claim 14, wherein the acoustic wave device is structured to generate bulk waves in a thickness-shear mode.

16. The acoustic wave device according to claim 15, wherein, where a thickness of the piezoelectric layer is d and a center-to-center distance between adjacent two of the first electrode finger and the second electrode finger is p, d/p≤about 0.5.

17. The acoustic wave device according to claim 16, wherein the d/p is less than or equal to about 0.24.

18. The acoustic wave device according to claim 1, wherein a region in which the first electrode finger and the second electrode finger overlap each other when viewed in the third direction is an excitation region, and, where a metallization ratio of the first electrode finger and the second electrode finger to the excitation region is MR, MR≤about 1.75(d/p)+0.075 is satisfied.

19. The acoustic wave device according to claim 1, wherein the acoustic wave device is structured to generate plate waves.

20. The acoustic wave device according to claim 14, wherein Euler angles (φ, θ, ψ) of the lithium niobate or the lithium tantalate fall within a range of expression (1), expression (2), or expression (3):
(0°±10°,0° to 20°, any ψ) (1);
(0°±10°,20° to 80°,0° to 60° (1−(θ−50)²/900)^{1/2}) or (0°±10°,20° to 80°,[180°−60° (1−(θ−50)²/900)^{1/2}] to 180°) (2); and
(0°±10°,[180°−30° (1−(ψ−90)²/8100)^{1/2}] to 180°, any ψ) (3).
